(19) United States
(12) Patent Application Publication
(10) Pub. No.: US 2010/0148295 A1
(43) Pub. Date: Jun. 17, 2010

(54) BACK-ILLUMINATED CMOS IMAGE SENSORS

(76) Inventors: Frederick T. Brady, Rochester, NY (US); Robert M. Guidash, Rochester, NY (US)

Correspondence Address: Pedro P. Hernandez;Patent Legal Staff, Eastman Kodak Company, 343 State Street, Rochester, NY, 14650-2201, US

(21) Appl. No.: 12/565,182

(22) Filed: Sep. 23, 2009

Related U.S. Application Data
(60) Provisional application No. 61/122,846, filed on Dec. 16, 2008.

(51) Int. Cl. H01L 31/0352; H01L 29/00; H01L 31/02; H01L 21/76

(52) U.S. Cl. 257/447; 257/618; 257/460; 438/424; 257/E29.001; 257/E31.032; 257/E31.11; 257/E21.54

(57) ABSTRACT

A semiconductor wafer includes one or more back-illuminated image sensors each formed in a portion of the semiconductor wafer. One or more thinning etch stops are formed in other portions of the semiconductor wafer.

### CROSS REFERENCE TO RELATED APPLICATION

This application claims the benefit of U.S. Provisional Application No. 61/122,846 filed on Dec. 16, 2008, which is incorporated herein by reference.

### TECHNICAL FIELD

The present invention relates generally to image sensors for use in digital cameras and other types of image capture devices, and more particularly to back-illuminated image sensors. Still more particularly, the present invention relates to a method for thinning semiconductor wafers during fabrication of back-illuminated image sensors.

### BACKGROUND

An electronic image sensor captures images using light-sensitive photosensitive sites that convert incident light into electrical signals. Image sensors are generally classified as either front-illuminated image sensors or back-illuminated image sensors. FIG. 1 is a simplified illustration of a fabrication step for a back-illuminated image sensor in accordance with the prior art. At this stage of the fabrication process, image sensor 100 includes a number of photosensitive sites 102 formed in a sensor layer 104. Circuit layer 106 is positioned between support wafer 108 and sensor layer 104. Circuit layer 106 is electrically connected to sensor layer 104 through one or more conductive interconnects 110 formed within circuit layer 106.

During this fabrication step, substrate 112 is chemically etched to expose the backside surface 114 of sensor layer 104. Typically, the etch rate of silicon, the material that forms substrate 112, is different from the etch rate of the material of sensor layer 104. These different etch rates allows the interface between substrate 112 and sensor layer 104 to be used as an etch stop. One limitation to this etch process is that it does not reliably stop at the interface. Consequently, it can be difficult to maintain a uniform and repeatable thickness for sensor layer 104.

Constructing a back-illuminated image sensor on a Silicon-On-Insulator (SOI) wafer solves this issue. FIG. 2 is a simplified cross section view of the same fabrication step shown in FIG. 1 for a back-illuminated image sensor on an SOI wafer in accordance with the prior art. With an SOI wafer, insulating layer 200 is disposed between sensor layer 106 and substrate 112. Insulating layer 200 has high etch selectivity relative to silicon, making it much easier to achieve a uniform and repeatable sensor layer thickness. However, SOI wafers are very expensive, rendering this construction of a back-illuminated image sensor less desirable.

Accordingly, a need exists for improved processing techniques for forming back-illuminated image sensors.

### SUMMARY

Briefly summarized, according to one aspect of the invention, one or more back-illuminated image sensors are fabricated on portions of a semiconductor wafer, and one or more thinning etch stops are constructed on other portions of the semiconductor wafer. The thinning etch stops can be fabricated wherever the etch stops can fit on the wafer, including, but not limited to, the scribe region and regions that do not include pixel circuitry or other components. Each thinning etch stop includes a trench formed in the wafer, an etch stop layer formed along the sidewall and bottom surfaces of the trench, and an insulating material that fills the trench. An optional insulating layer can be grown on the sidewall and bottom surfaces of the trench prior to the formation of the etch stop layer.

### ADVANTAGEOUS EFFECT OF THE INVENTION

Including thinning etch stops in portions of the semiconductor wafer results in a reliable and repeatable etching process for back-illuminated image sensors. Additionally, the cost to fabricate back-illuminated image sensors is reduced relative to SOI wafers.

### BRIEF DESCRIPTION OF THE DRAWINGS

The invention will become more apparent by reference to the following detailed description of the invention taken in conjunction with the accompanying drawings. The elements of the drawings are not necessarily to scale relative to each other.

FIG. 1 is a simplified illustration of a fabrication step for a back-illuminated image sensor in accordance with the prior art;

FIG. 2 is a simplified cross section view of the same fabrication step shown in FIG. 1 for a back-illuminated image sensor on an SOI wafer in accordance with the prior art;

FIG. 3 is a simplified block diagram of an image capture device in an embodiment in accordance with the invention;

FIG. 4 is a simplified block diagram of image sensor 306 shown in FIG. 3 in an embodiment in accordance with the invention;

FIG. 5 is a simplified top view of a semiconductor wafer during fabrication of image sensors in an embodiment in accordance with the invention; and

FIGS. 6-16 are simplified cross section views along line A-A′ shown in FIG. 5 in an embodiment in accordance with the invention.

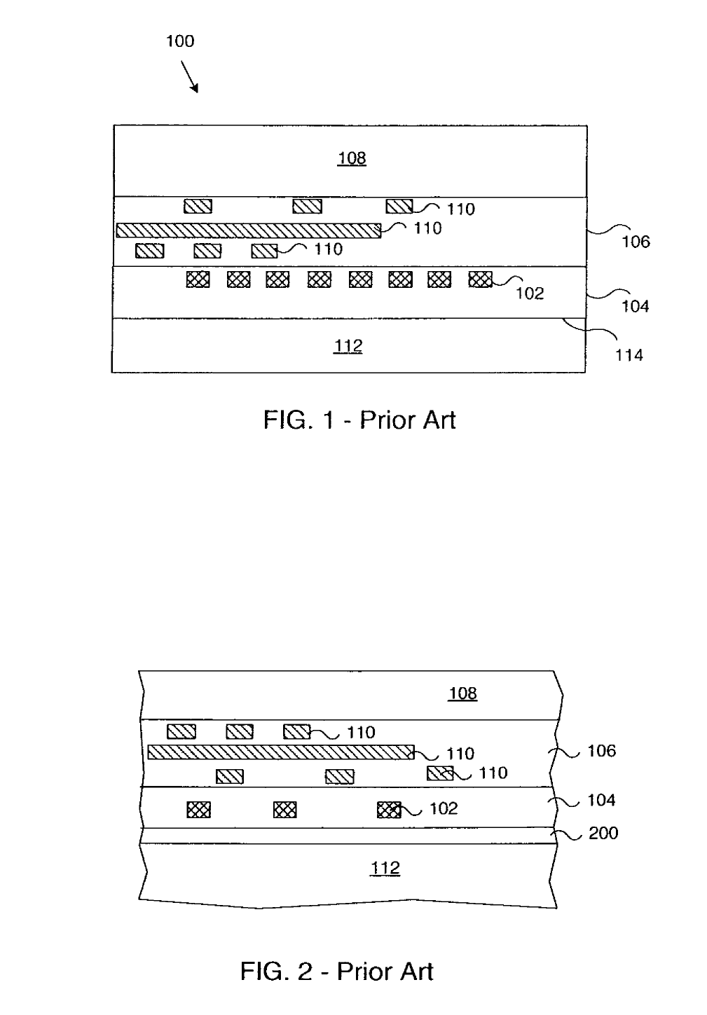

### DETAILED DESCRIPTION

Throughout the specification and claims the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

Additionally, the terms “wafer” and “substrate” are to be understood as a semiconductor-based material including, but not limited to, silicon, silicon-on-insulator (SOI) technology, silicon-on-sapphire (SOS) technology, doped and undoped semiconductors, epitaxial layers formed on a semiconductor substrate, and other semiconductor structures.

Referring to the drawings, like numbers indicate like parts throughout the views.

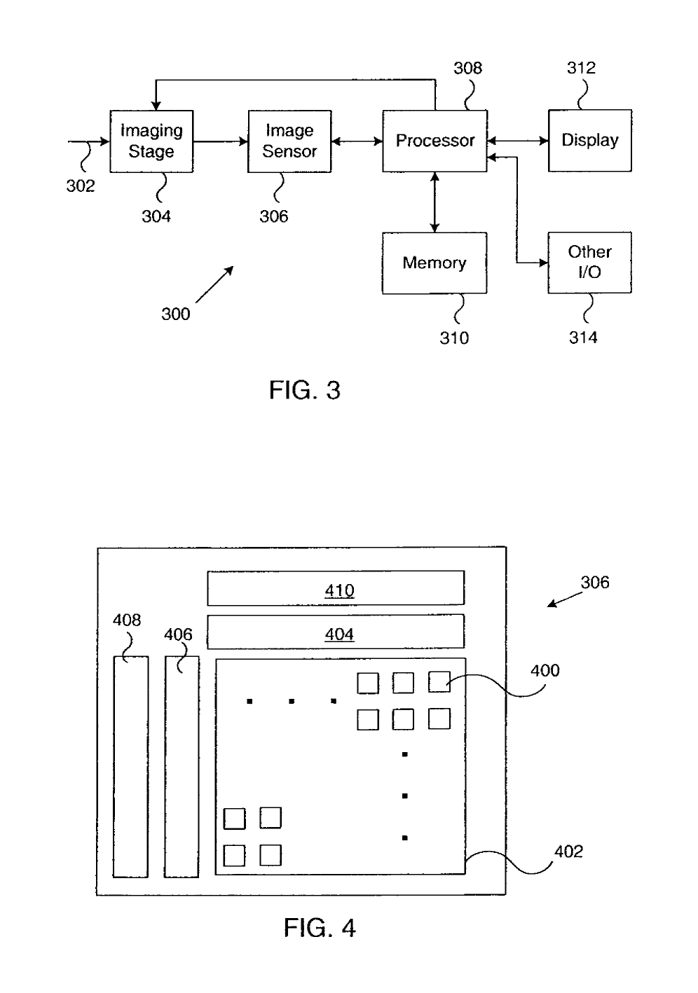

FIG. 3 is a simplified block diagram of an image capture device in an embodiment in accordance with the invention. Image capture device 300 is implemented as a digital camera in FIG. 3. Those skilled in the art will recognize that a digital camera is only one example of an image capture device that can utilize an image sensor incorporating the present invention. Other types of image capture devices, such as, for example, cell phone cameras, scanners, and digital video camcorders, can be used with the present invention.

In digital camera 300, light 302 from a subject scene is input to an imaging stage 304. Imaging stage 304 can include conventional elements such as a lens, a neutral density filter, an iris and a shutter. Light 302 is focused by imaging stage 304 to form an image on image sensor 306. Image sensor 306 captures one or more images by converting the incident light into electrical signals. Digital camera 300 further includes processor 308, memory 310, display 312, and one or more additional input/output (I/O) elements 314. Although shown as separate elements in the embodiment of FIG. 3, imaging stage 304 may be integrated with image sensor 306, and possibly one or more additional elements of digital camera 300, to form a camera module. For example, a processor or a memory may be integrated with image sensor 306 in a camera module in embodiments in accordance with the invention.

Processor 308 may be implemented, for example, as a microprocessor, a central processing unit (CPU), an application-specific integrated circuit (ASIC), a digital signal processor (DSP), or other processing device, or combinations of multiple such devices. Various elements of imaging stage 304 and image sensor 306 may be controlled by timing signals or other signals supplied from processor 308.

Memory 310 may be configured as any type of memory, such as, for example, random access memory (RAM), read-only memory (ROM), Flash memory, disk-based memory, removable memory, or other types of storage elements, in any combination. A given image captured by image sensor 306 may be stored by processor 308 in memory 310 and presented on display 312. Display 312 is typically an active matrix color liquid crystal display (LCD), although other types of displays may be used. The additional I/O elements 314 may include, for example, various on-screen controls, buttons or other user interfaces, network interfaces, or memory card interfaces.

It is to be appreciated that the digital camera shown in FIG. 3 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

Referring now to FIG. 4, there is shown a simplified block diagram of image sensor 306 shown in FIG. 3 in an embodiment in accordance with the invention. Image sensor 306 typically includes an array of pixels 400 that form an imaging area 402. Image sensor 306 further includes column decoder 404, row decoder 406, digital logic 408, and analog or digital output circuits 410. Image sensor 306 is implemented as a back-illuminated Complementary Metal Oxide Semiconductor (CMOS) image sensor in an embodiment in accordance with the invention. Thus, column decoder 404, row decoder 406, digital logic 408, and analog or digital output circuits 410 are implemented as standard CMOS electronic circuits that are electrically connected to imaging area 402.

Functionality associated with the sampling and readout of imaging area 402 and the processing of corresponding image data may be implemented at least in part in the form of software that is stored in memory 310 (see FIG. 3) and executed by processor 308. Portions of the sampling and readout circuitry may be arranged external to image sensor 306, or formed integrally with imaging area 402, for example, on a common integrated circuit with photosensitive sites and other elements of the imaging area. Those skilled in the art will recognize that other peripheral circuitry configurations or architectures can be implemented in other embodiments in accordance with the invention.

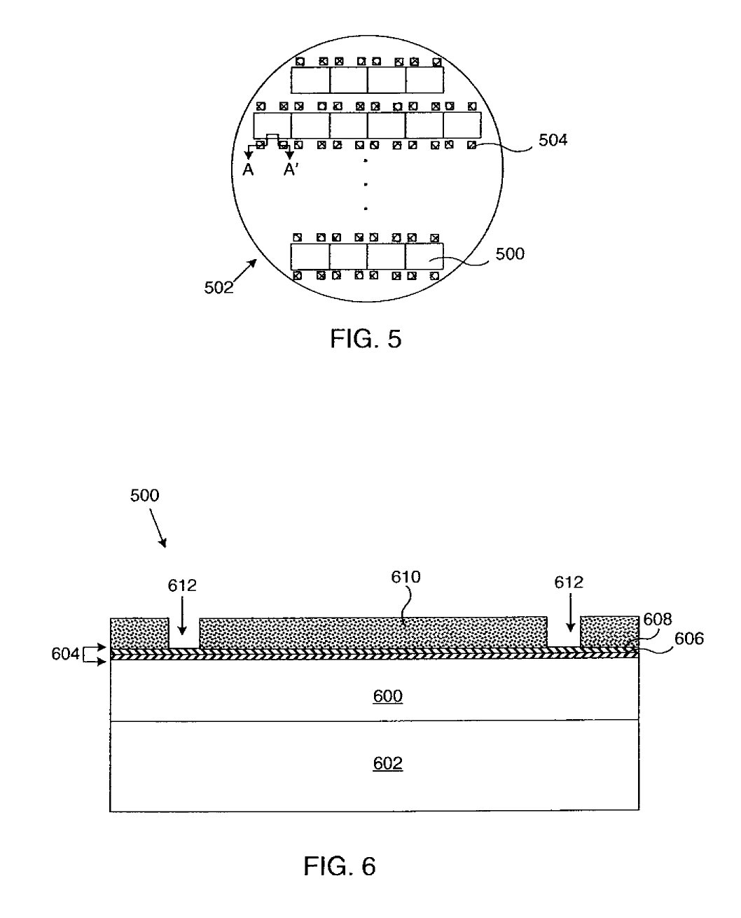

FIG. 5 is a simplified top view of a semiconductor wafer during fabrication of image sensors in an embodiment in accordance with the invention. A number of back-illuminated image sensors 500 are fabricated on wafer 502. Image sensors 500 are configured as Complementary Metal Oxide Semiconductor (CMOS) image sensors in an embodiment in accordance with the invention.

Thinning etch stops 504 are formed in wafer 502. Thinning etch stops 504 are fabricated early in the CMOS fabrication process, preferably prior to implants that are sensitive to thermal processing steps in an embodiment in accordance with the invention. Although thinning etch stops 504 are shown adjacent to image sensors 500 in FIG. 5, in practice thinning etch stops 504 can be fabricated wherever the etch stops can fit on wafer 502, including, but not limited to, the scribe region and regions that do not include any pixel circuitry or other image sensor components.

Referring now to FIGS. 6-15, there are shown simplified cross section views along line A-A′ in FIG. 5 in an embodiment in accordance with the invention. FIG. 6 shows wafer 500 after a number of initial CMOS fabrication steps have been completed. Wafer 500 at this stage includes epitaxial layer 600 formed over substrate 602. As discussed earlier, wafer 500 can be implemented with other semiconductor-based materials, including, but not limited to, silicon, silicon-on-insulator (SOI) technology, silicon-on-sapphire (SOS) technology, and doped and undoped semiconductors.

The initial thickness of epitaxial layer 600 is preferably greater than the final desired thickness of the sensor layer. For example, the initial thickness of epitaxial layer 600 is 2.5 micrometers or greater in an embodiment in accordance with the invention.

Epitaxial layer 600 and substrate 602 have been doped with one or more p-type dopants or one or more n-type dopants. By way of example only, epitaxial layer 600 is implemented as a p-epitaxial layer and substrate 602 as a p+ substrate in an embodiment in accordance with the invention.

Insulating layer 604 is formed over epitaxial layer 600. Insulating layer 604 includes oxide layer 606 and nitride layer 608 in an embodiment in accordance with the invention. Mask layer 610 is formed over insulating layer 604 and patterned to create openings 612. Mask layer 610 is implemented as a photoresist mask that is deposited over insulating layer 604 in an embodiment in accordance with the invention.

The locations of openings 612 correspond to the locations where thinning etch stops will be formed. The width of openings 612 depends on the etch depth of thinning etch stops. By way of example only, the width of openings 612 is typically between one-half to one-third the etch depth in an embodiment in accordance with the invention.

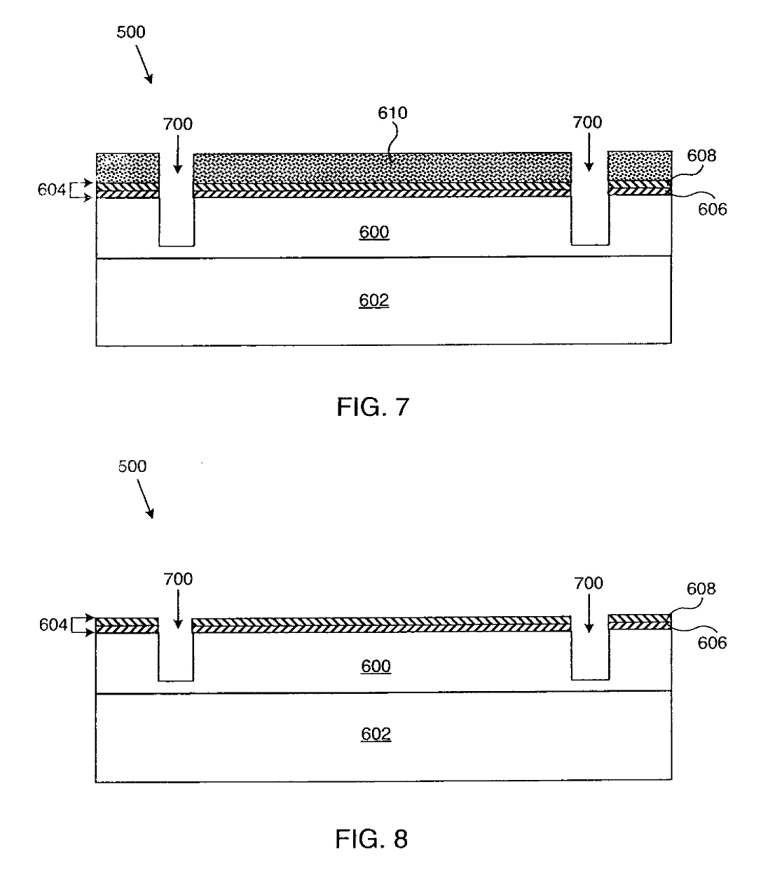

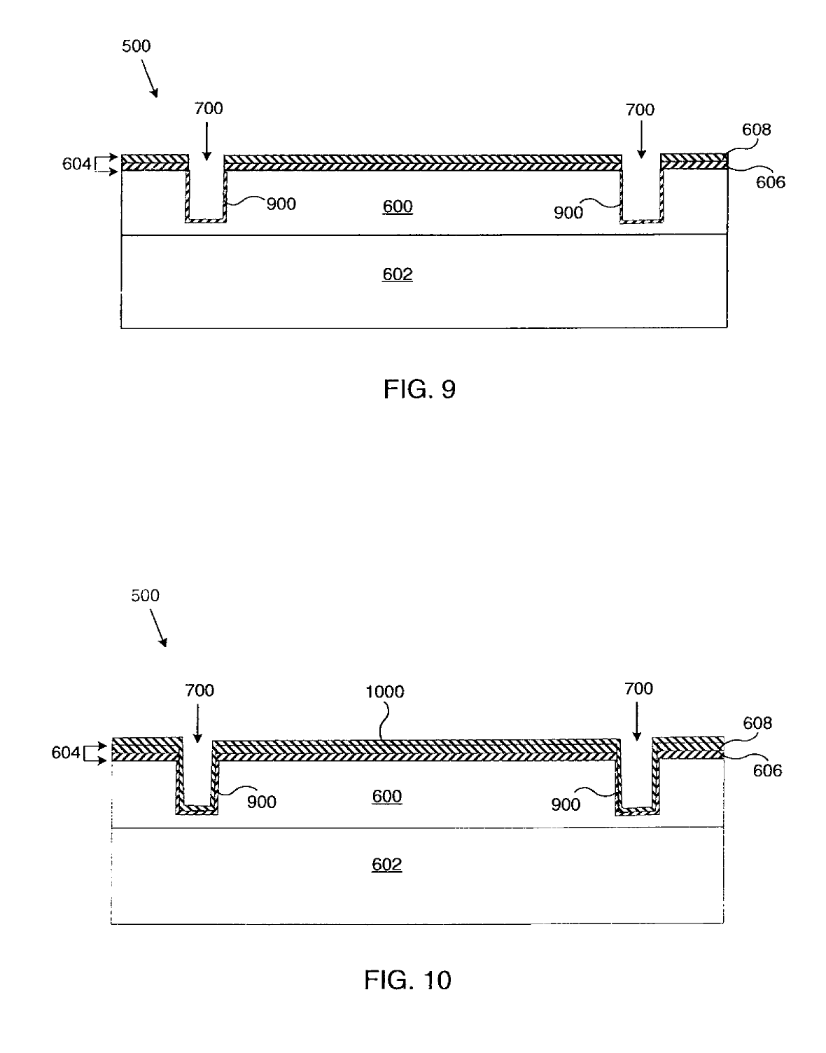

Next, as shown in FIG. 7, the portions of insulating layer 604 and epitaxial layer 600 exposed in openings 612 are etched to create trenches 700. Mask layer 610 is then removed (FIG. 8) and liner insulating layer 900 is formed on the sidewall and bottom surfaces of trenches 700 (FIG. 9). Liner insulating layer 900 is optional and is configured as a layer of oxide that is grown on the sidewall and bottom surfaces in an embodiment in accordance with the invention. By way of example only, liner insulating layer 900 has a thickness of one hundred Angstroms or less in an embodiment in accordance with the invention.

An etch stop layer 1000 is then formed over wafer 500 (FIG. 10). Etch stop layer 1000 is implemented as a silicon nitride layer in an embodiment in accordance with the invention. Etch stop layer 1000 has a thickness in trenches 700 that is sufficient to withstand the subsequent backside thinning of wafer 500. The backside thinning of wafer 500 can be achieved by performing a Chemical Mechanical Polishing (CMP) process in an embodiment in accordance with the invention. With a CMP process, etch stop layer 1000 has a thickness of at least 0.2 micrometers in an embodiment in accordance with the invention.

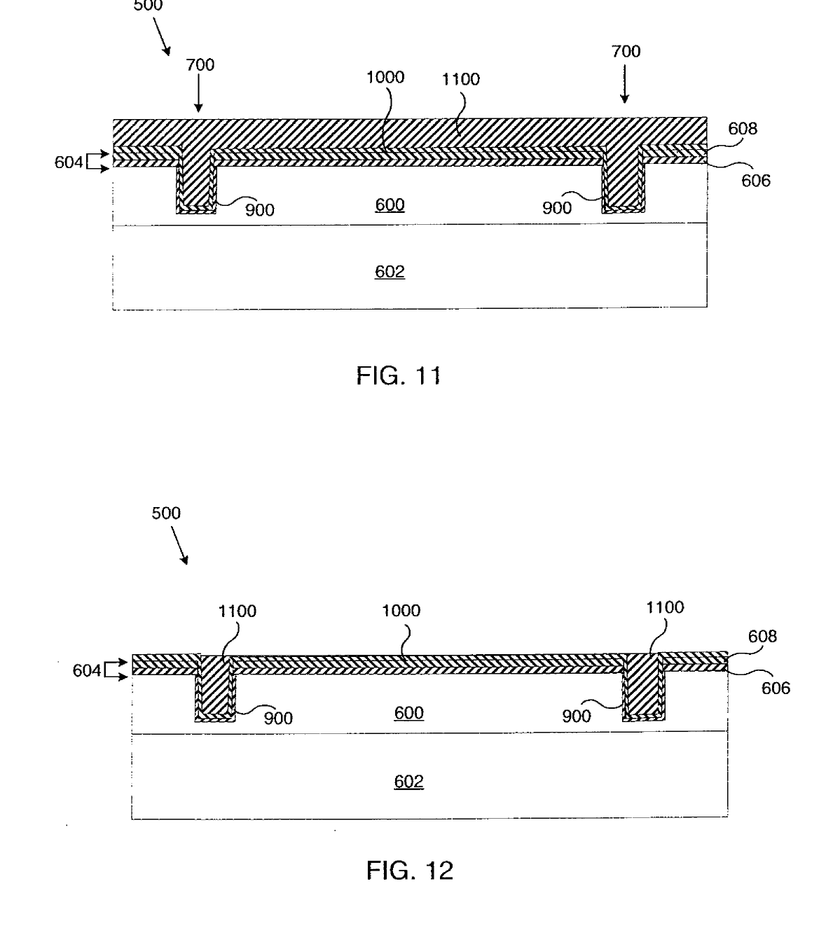

Next, as shown in FIG. 11, insulating material 1100 is formed over wafer 500 and fills trenches 700. Insulating material 1100 is configured as an oxide layer that is deposited over wafer 500 in an embodiment in accordance with the invention. Insulating material 1100 is then planarized so that the top surface of insulating material 1100 in trenches 700 is planar with the top surface of etch stop layer 1000 (FIG. 12). If desired, the oxide layer can be densified before or after planarization of insulating material 1100. A CMP process is performed to planarize insulating material 1100 in an embodiment in accordance with the invention.

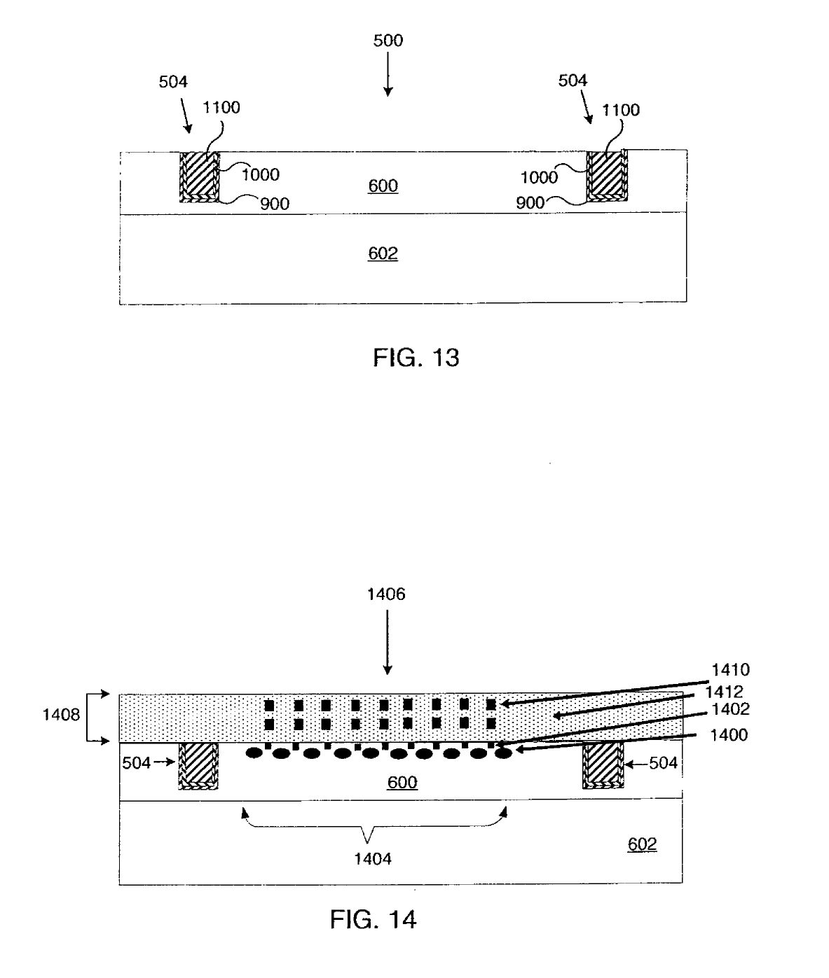

Etch stop layer 1000, insulating layer 604, and the top portions of insulating material 1100 in trenches 700 are then removed, as shown in FIG. 13. The nitride layer 608 in insulating layer 604 is removed with a hot phosphoric dip, and the oxide layer 606 and insulating material 1100 with an HF-based dip in an embodiment in accordance with the invention.

Formation of thinning etch stops 1300 is now complete. Thinning etch stops 1300 include liner insulating layer 900 overlying the sidewall and bottom surfaces of trenches 700 with etch stop layer 1000 overlying liner insulating layer 900. The trenches are also filled with insulating material 1100. In those embodiments where liner insulating layer 900 is not formed, etch stop layer 1000 is disposed along the sidewall and bottom surfaces of trenches 700.

Conventional processing steps are now performed on wafer 500 to complete the fabrication of back-illuminated image sensors 500 (FIG. 14). For example, for a CMOS image sensor, photosensitive sites 1400 are formed in epitaxial layer 600 with trench isolation regions 1402 formed between the photosensitive sites. Photosensitive sites form an imaging area 1404 for a CMOS image sensor 1406. Circuit layer 1408 is disposed on epitaxial layer 600 and is electrically connected to the photosensitive sites through one or more conductive interconnects 1410 and other features formed in insulating layer 1412.

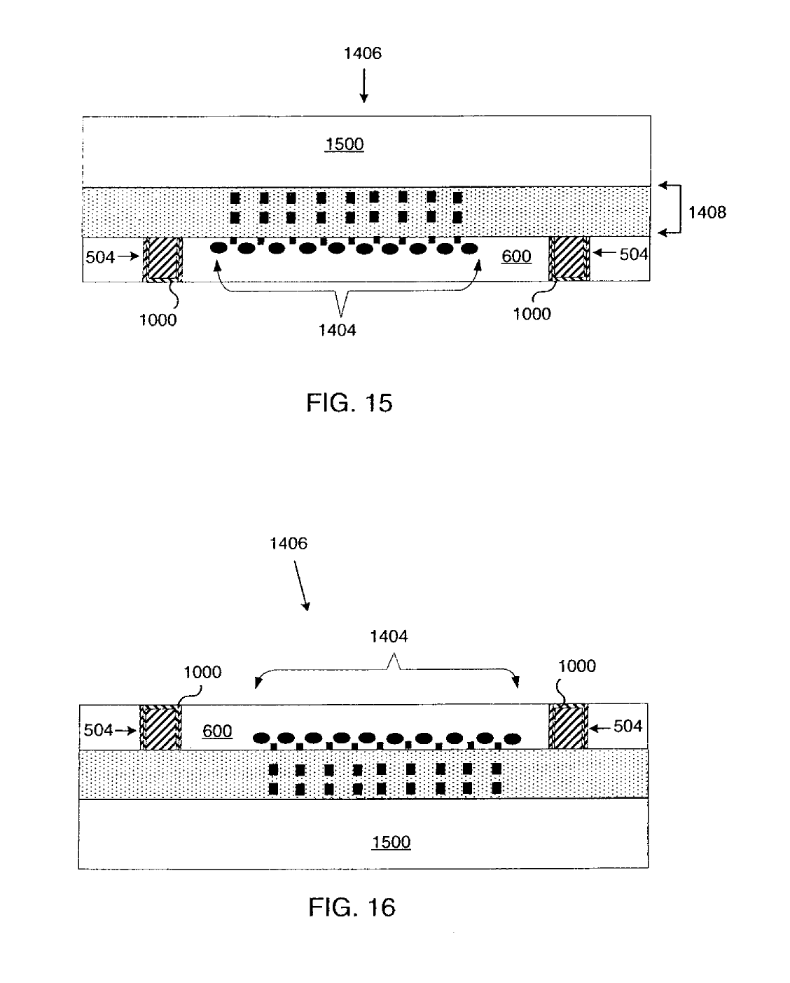

At some point during the fabrication of the back-illuminated image sensors, a handle or support wafer 1500 is attached to the frontside of circuit layer 1404 and substrate 602 removed (FIG. 15). Substrate 602 is removed by grinding, polishing, and performing a CMP process on substrate 602 in an embodiment in accordance with the invention. Etch stop layer 1000 in thinning etch stops 504 acts as an etch stop during the grinding, polishing, and CMP processes. By way of example only, handle wafer 1500 can be implemented as a simple silicon wafer or a silicon wafer with devices that electrically interface with epitaxial layer 600. After thinning, the wafer is flipped over (FIG. 16) and image sensor 1406 can be used for backside imaging, either immediately or after further backside processing to reduce dark current or after the addition of a color filter array or the microlenses.

The invention has been described with reference to particular embodiments in accordance with the invention. However, it will be appreciated that variations and modifications can be effected by a person of ordinary skill in the art without departing from the scope of the invention. By way of example only, the present invention can be used in back-illuminated image sensors other than CMOS back-illuminated image sensors.

Additionally, even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

For example, a semiconductor wafer can include one or more thinning etch stops formed therein, with at least one thinning etch stop including a trench formed in a portion of the semiconductor wafer; and an etch stop layer disposed on the sidewall and bottom surfaces of the trench, wherein the trench is filled with an insulating layer. A semiconductor wafer can include one or more back-illuminated image sensors each formed in a portion of the semiconductor wafer; and one or more thinning etch stops each formed in another portion of the semiconductor wafer. At least one thinning etch stop can include a trench formed in a portion of the semiconductor wafer; and an etch stop layer disposed on the sidewall and bottom surfaces of the trench, wherein the trench is filled with an insulating layer. The at least one thinning etch stop can be disposed in a scribe region, a region that does not include any pixel circuitry or other image sensor components, or adjacent to an image sensor formed on the semiconductor wafer.

A method for fabricating a thinning etch stop in a semiconductor wafer can include forming a trench in a portion of the semiconductor wafer; forming an etch stop layer along the sidewall and bottom surfaces of the trench; and filling the trench with an insulating material. A liner insulating layer can be formed on the sidewall and bottom surfaces of the trench prior to forming the etch stop layer along the sidewall and bottom surfaces of the trench. The trench can be formed in a portion of the semiconductor wafer by forming a mask layer on the semiconductor wafer; patterning the mask layer to create an opening where the trench is to be formed; etching the portion of the semiconductor wafer exposed in the opening; and removing the mask layer.

### PARTS LIST

100 back-illuminated image sensor
102 photosensitive sites
104 sensor layer
106 circuit layer
108 support wafer
110 conductive interconnects
112 substrate
114 backside surface of sensor layer
200 insulating layer
300 image capture device
302 light
304 imaging stage
306 image sensor
308 processor
310 memory
312 display
314 additional input/output (I/O) elements
400 pixel
402 imaging area
404 column decoder
406 row decoder
408 digital logic
410 analog or digital output circuits
500 back-illuminated image sensor
502 semiconductor wafer
504 thinning etch stops
600 epitaxial layer
602 substrate
604 insulating layer
606 oxide layer
608 nitride layer
610 mask layer
612 openings
700 trench
900 liner insulating layer
1000 etch stop layer
1100 insulating material
1400 photosensitive sites
1402 trench isolation
1404 imaging area
1406 CMOS image sensor
1408 circuit layer
1410 conductive interconnects
1412 insulating layer
1500 support wafer

1. A semiconductor wafer comprising one or more thinning etch stops formed therein, wherein at least one thinning etch stop comprises:
a trench formed in a portion of the semiconductor wafer; and
an etch stop layer disposed on the sidewall and bottom surfaces of the trench, wherein the trench is filled with an insulating layer.

2. A semiconductor wafer, comprising:
one or more back-illuminated image sensors each formed in a portion of the semiconductor wafer; and
one or more thinning etch stops each formed in another portion of the semiconductor wafer.

3. The semiconductor wafer of claim 2, wherein at least one thinning etch stop is disposed in a scribe region.

4. The semiconductor wafer of claim 2, wherein at least one thinning etch stop is disposed adjacent to an image sensor formed on the semiconductor wafer.

5. The semiconductor wafer of claim 2, wherein at least one thinning etch stop comprises:
a trench formed in a portion of the semiconductor wafer; and
an etch stop layer disposed on the sidewall and bottom surfaces of the trench, wherein the trench is filled with an insulating layer.

6. A method for fabricating a thinning etch stop in a semiconductor wafer, the method comprising:
forming a trench in a portion of the semiconductor wafer;
forming an etch stop layer along the sidewall and bottom surfaces of the trench; and
filling the trench with an insulating material.

7. The method of claim 6, wherein forming a trench in a portion of the semiconductor wafer comprises:
forming a mask layer on the semiconductor wafer;
patterning the mask layer to create an opening where the trench is to be formed;
etching the portion of the semiconductor wafer exposed in the opening; and
removing the mask layer.

8. The method of claim 6, further comprising forming a liner insulating layer on the sidewall and bottom surfaces of the trench prior to forming the etch stop layer along the sidewall and bottom surfaces of the trench.
